(19) United States
(12) Patent Application Publication
(10) Pub. No.: US 2022/0143709 A1
(43) Pub. Date: May 12, 2022

(54) X-RAY REFERENCE OBJECT, X-RAY DETECTOR, ADDITIVE MANUFACTURING APPARATUS AND METHOD FOR CALIBRATING THE SAME

(71) Applicant: Arcam AB, Mölnlycke (SE)

(72) Inventor: Christian EKBERG, Hindas (SE)

(73) Assignee: Arcam AB, Mölnlycke (SE)

(21) Appl. No.: 17/416,209

(22) PCT Filed: Mar. 1, 2019
(86) PCT No.: PCT/EP2019/055166

§ 371 Date: Jun. 18, 2021

Related U.S. Application Data
(60) Provisional application No. 62/801,493, filed on Feb. 5, 2019.
(60) Provisional application No. 62/782,897, filed on Dec. 20, 2018.

(51) Int. Cl. B22F 12/90; H01J 37/305; H01J 37/30; B22F 10/80; B22F 12/41

(52) U.S. Cl. CPC B22F 12/90; H01J 37/305; H01J 37/3005; B33Y 50/00; B22F 12/41; H01J 2237/2445; H01J 2237/30472; B22F 10/80

(57) ABSTRACT

The present specification relates to an additive manufacturing apparatus comprising an X-ray reference object (18) for calibrating an electron beam unit in the additive manufacturing apparatus by detecting X-rays generated by sweeping an electron beam from the electron beam unit over a reference surface (19) of the X-ray reference object (18) and processing the detected signals, the X-ray reference object (18) comprising a support body (20) that has a top surface (21) and comprises a plurality of holes (22) in the top surface (21), The X-ray reference object (18) comprises a plurality of target members (23) inserted into the plurality of holes (22) of the support body (20). The present specification also relates to an X-ray detector to be used in the additive manufacturing apparatus, and to a method for calibrating such an additive manufacturing apparatus.

### CROSS REFERENCE TO RELATED APPLICATIONS

This specification is a National Phase Entry of International Application No. PCT/EP2019/055166 filed Mar. 1, 2019 and entitled “X-RAY REFERENCE OBJECT, X-RAY DETECTOR, ADDITIVE MANUFACTURING APPARATUS AND METHOD FOR CALIBRATING THE SAME” which itself claims priority to and the benefit of U.S. Provisional Patent Application No. 62/782,897, filed on Dec. 20, 2018, and U.S. Provisional Patent Application No. 62/801,493, filed on Feb. 5, 2019; the contents of each of which are hereby incorporated by reference in their entirety.

### BACKGROUND

### Related Field

The present invention relates generally to the field of apparatus and methods for additive manufacturing of a three-dimensional article by successively fusing layer by layer of powder material by means of an electron beam, e.g. Electron Beam Melting (EBM) machines. Further, the present invention relates particularly to the field of electron beam control in additive manufacturing machines. The invention relates to a new technique for calibrating an electron beam unit in an additive manufacturing apparatus.

The invention relates specifically to an X-ray reference object for calibrating an electron beam unit in an additive manufacturing apparatus, wherein the X-ray reference object comprises a support body that has a top surface. The invention relates also to an X-ray detector for detecting X-rays during calibration of the electron beam unit, wherein the X-ray detector comprises a photo detector. The invention relates also to an additive manufacturing apparatus for forming a three-dimensional article through successively depositing individual layers of powder material that are fused together with an electron beam from an electron beam unit so as to form the article according to a computer model thereof, wherein the additive manufacturing apparatus uses the inventive technique. The invention relates also to a method for calibrating an electron beam unit of an additive manufacturing apparatus, the additive manufacturing apparatus comprising a control unit and an X-ray reference object located in the work area of the additive manufacturing apparatus, wherein X-rays are generated by sweeping an electron beam from an electron beam unit over a reference surface of the X-ray reference object. The invention relates also to an associated computer program product.

### Description of Related Art

Free-form fabrication or additive manufacturing is a method for forming three-dimensional articles through successive fusion of chosen parts of powder layers applied to a worktable.

Equipment for producing a three-dimensional article layer by layer using a powdery material which can be solidified by irradiating it with electromagnetic radiation or an electron beam are known from various patents. Such equipment include for instance a supply of powder, means for applying a layer of powder on a work table on which the three-dimensional article is to be formed, an electron beam source for delivering an electron beam spot to the powder bed and means for directing the high energy beam or electron beam over the work area. The powder sinters or melts and solidifies as the electron beam spot is moved over the work area, whereupon the three-dimensional article is formed successively layer by layer.

In additive manufacturing a short manufacturing time and high quality of the finalized product is of outmost importance. The applicant produces machines for additive manufacturing providing short manufacturing times of three-dimensional articles having high quality, and during such and other additive manufacturing the electromagnetic focus coil or focusing lens is used to focus and defocus the electron beam spot on the work area, i.e. change the size of the electron beam spot. Besides the electromagnetic focus coil, the electron beam unit also comprises an astigmatism coil/lens for shaping the electron beam spot and a deflection coil/lens for directing/moving the electron beam spot over the work area. The coils of the electromagnetic beam unit are supplied with appropriate drive current. The desired shape and material properties of the final three dimensional articles depend on the ability to control the electron beam, i.e. the accuracy of the electron beam spot. Thus, to obtain a correct melting of the powder material at specific locations there is a need to inter alia have complete correspondence between the true position, size and shape of the electron beam spot and the set/wanted position, size and shape of the electron beam spot. However, due to electromagnetic disturbances from the environment, physical vibration of the additive manufacturing apparatus, non-ideal components in the electron beam unit, etc. the electron beam spot risk having deficient/imperfect shape, size and/or position resulting in a poor-quality three-dimensional article. It is also a risk that the magnetic field from the electromagnetic focus coil may interact with the astigmatism coil and/or the deflection coil, which results in interference or cross-talk between these coils, resulting in incorrect electron beam position, shape or size and thus a poor-quality three-dimensional article.

Thus, there is a need within the technical field to easily verify whether the electron beam spot has correct shape, size and/or position.

The applicants own US 2017/087661, disclose a calibration plate comprising an upper plate having through holes and a lower plate arranged below the upper plate, wherein the upper plate and the lower plate are arranged at a distance of about 5-10 cm from each other. The through holes have predetermined shape and positions, and preferably four through holes are arranged in a matrix providing a cross. When the calibration plate, especially the crosses, is battered with electrons, X-rays will be generated and irradiated back from the upper plate to a sensor/detector, but when the electrons pass through the through holes of the upper plate and collide with the lower plate instead, the generated X-rays will not find their way back through the through holes and to the sensor. Thus, when X-rays are detected by the sensor the electron beam spot hits the cross and when no X-rays are detected by the sensor the electron beam spot hits the lower plate. The position of the crosses are known and predetermined, and these positions are compared with the measured/detected position of the crosses, and when there is a deviation the electron beam unit is calibrated/adjusted. This design having a cross requires that the thickness of the material making up the cross need to be quite thin, i.e. less than 0.2 millimeters, in order to minimize the generation, emanation, and/or emission of X-rays from the sides of the cross bars, i.e. from within the through holes, in order to achieve an acceptable signal/noise ratio. This calibration plate design has perfect performance during calibration using an electron beam current of about 2.0-2.5 mA, and an accelerating voltage of the electron beam unit equal to or lower than 60 kV.

The inventor and the applicant have concluded that there is a need to increase the electron beam current and/or the accelerating voltage during calibration in order to match future electron beam melting machines having increased electron beam current and/or accelerating voltage during production of the three-dimensional article. The calibration/adjustment of the electron beam unit will be more efficient if the calibration is performed during circumstances more similar to the production. However, when increasing the energy content of the electron beam the thin cross risks becoming distorted/damaged, i.e. jeopardizing the entire calibration/adjustment.

For this reason there is a need within the EBM field to further improve the electron beam control and performance, and especially there is a need to find an improved calibration solution, i.e. a technique to verify that the electron beam spot has correct shape, size and/or position, wherein the calibration solution is especially suited for higher electron beam current and/or accelerating voltage than previously used.

### SUMMARY

The present invention aims at obviating the aforementioned disadvantages and failings of previously known apparatus/machines for additive manufacturing of a three-dimensional article, and at providing an improved apparatus, which machine exhibits improved electron beam control and performance compared to conventional machines due to improved calibration accuracy in production-like circumstances. A primary object of the present invention is to provide a new calibration technique for calibrating an electron beam unit of an additive manufacturing apparatus, wherein the new calibration technique is accurate and easy to use.

According to the invention at least the primary object is attained by means of the initially defined X-ray reference object, X-ray detector, apparatus and method having the features defined in the independent claims. Preferred embodiments of the present invention are further defined in the dependent claims.

According to a first aspect of the present invention, there is provided an X-ray reference object of the initially defined type, wherein the X-ray reference object comprises a plurality of target members at the top surface of the support body.

According to a second aspect of the present invention, there is provided an X-ray detector of the initially defined type, wherein the X-ray detector comprises a scintillator arranged in front of the photo detector and a spectral filter arranged in front of the scintillator, such that X-rays originating from the X-ray reference object penetrates through the spectral filter and are absorbed by the scintillator.

According to a third aspect of the present invention, there is provided an additive manufacturing apparatus, wherein the additive manufacturing apparatus comprises the X-ray reference object, an X-ray detector and a control unit operatively connected to the X-ray detector and configured for controlling the electron beam unit.

According to a forth aspect of the present invention, there is provided a method for calibrating an electron beam unit of such an additive manufacturing apparatus, wherein the X-ray reference object is located in the work area of the additive manufacturing apparatus, the calibration method comprising the steps of: sweeping an electron beam from the electron beam unit over the reference surface of the X-ray reference object, for each target member in the reference surface of the X-ray reference object: detecting X-rays originating from the X-ray reference object when the electron beam is swept over the target member, processing the detected signals, determining in a control unit at least one real value of a parameter of the electron beam spot at the reference surface, and adjusting in the control unit the control of the electron beam unit when there is a difference between the at least one real value and a corresponding target value of the parameter of the electron beam spot, in order to have the at least one real value approaching the target value.

According to a fifth aspect of the present invention, there is provided a computer program product comprising at least one non-transitory computer-readable storage medium having computer-readable program code portions embedded therein, wherein the X-ray reference object is located in the work area of the additive manufacturing apparatus, wherein the computer-readable program code portions are configured to cause the additive manufacturing apparatus to execute the steps of the method in order to calibrate an electron beam unit of the additive manufacturing apparatus.

Thus, the present calibration technique invention is based on the idea to calibrate the electron beam unit of the additive manufacturing apparatus using a new X-ray reference object, such that higher electron beam current and/or accelerating voltage may be used during calibration without running the risk of local overheating or thermal distortion of the X-ray reference object. The calibration is further improved by using a new X-ray detector that is interrelated with the new X-ray reference object. Compared to prior art calibration techniques the inventive calibration technique provides for a better electron beam control and performance.

An exemplary advantage of the new X-ray reference object is that it is simple and inexpensive to manufacture in relation to previously known X-ray reference objects, at the same time as it provides for an accurate calibration of the electron beam unit before the manufacturing of the three-dimensional article in the additive manufacturing apparatus is started.

According to an exemplary embodiment of the present invention, the support body comprises a plurality of recesses/holes in the top surface, wherein the plurality of target members is inserted into the plurality of recesses. An exemplary advantage of at least this feature is that the position of the target members can be made with high accuracy/precision.

According to an exemplary embodiment of the present invention, the target members are in flush with the top surface of the support body providing a plane reference surface of the X-ray reference object. An exemplary advantage of at least this feature is that the edges of the target members and/or the edges of the holes of the support body are saved from being damaged, i.e. less edge erosion.

According to an exemplary embodiment of the present invention, the support body is solid and made of a metal or alloy comprising Copper (Cu). An exemplary advantage of at least this feature is that a support body of Copper has excellent thermal conductivity properties and will act as a heat sink preventing local overheating at the target members.

According to an exemplary embodiment of the present invention, the target members are made of a metal or alloy comprising one or more of Molybdenum (Mo), Tantalum (Ta), Wolfram (W), Niobium (Nb) and Zirconium (Zr). An exemplary advantage of at least this feature is that such target members will generate/produce a relatively high quantity of X-rays, and they have good resistivity against thermal deformation, and they provide for easy filtration of noise signals from the support body.

According to an exemplary embodiment of the present invention, the opening of the individual hole of the support body is circular or ring-shaped. An exemplary advantage of at least this feature is that this shape provides for a quick and reliable characterization of the electron beam spot, and makes it possible to sweep the electron beam in any and many directions over the target member.

According to an exemplary embodiment of the present invention, the light yield of the scintillator of the X-ray detector is equal to or more than 10 photons/keV, preferably equal to or more than 30 photons/keV. An exemplary advantage of at least this feature is that the photo detector of the X-ray detector can have much smaller active area than previously used X-ray detectors in additive manufacturing apparatus.

According to an exemplary embodiment of the present invention, the scintillator is not hygroscopic. An exemplary advantage of at least this feature is that the scintillator can be handled and mounted without special tools or enclosures.

According to an exemplary embodiment of the present invention, the decay time of the scintillator is equal to or less than 100 ns, preferably equal to or less than 50 ns. An exemplary advantage of at least this feature is that the after glowing of the scintillator will not have effect on the detection of subsequent X-rays.

According to an exemplary embodiment of the present invention, the spectral filter of the X-ray detector is configured to suppress X-ray bremsstrahlung, K-level emission lines and/or L-level emission lines having photon energies equal to or less than 15 keV. An exemplary advantage of at least this feature is that the filtration of background/noise signals from the support body can be significantly increased, i.e. the signal/noise ratio or signal/background ratio may be increased.

Further advantages with and features of the invention will be apparent from the other dependent claims as well as from the following detailed description of preferred embodiments.

### BRIEF DESCRIPTION OF THE DRAWINGS

With reference to the appended drawings, below follows a more detailed description of embodiments of the invention cited as examples.

In the drawings:

FIG. 1 is a schematic cross sectional side view of an electron beam melting (EBM) machine,

FIG. 2A is a schematic perspective view of an inventive X-ray reference object according to a first embodiment,

FIG. 2B is a schematic view from above of an inventive X-ray reference object according to a second embodiment,

FIG. 3A is a schematic view from above of a single target member according to a first embodiment,

FIG. 3B is a schematic view from above of a single target member according to a second embodiment,

FIG. 4 is a schematic cross sectional view of an inventive X-ray detector and an inventive X-ray reference object,

FIG. 5 is a schematic block diagram of an exemplary system according to various embodiments of the present invention,

FIG. 6A is a schematic block diagram of a server according to various embodiments of the present invention, and

FIG. 6B is a schematic block diagram of an exemplary mobile device according to various embodiments of the present invention.

### DETAILED DESCRIPTION OF EXAMPLE EMBODIMENTS

Various embodiments of the present invention will now be described more fully hereinafter with reference to the accompanying drawings, in which some, but not all embodiments of the invention are shown. Indeed, embodiments of the invention may be embodied in many different forms and should not be construed as limited to the embodiments set forth herein. Rather, these embodiments are provided so that this disclosure will satisfy applicable legal requirements. Unless otherwise defined, all technical and scientific terms used herein have the same meaning as commonly known and understood by one of ordinary skill in the art to which the invention relates. The term “or” is used herein in both the alternative and conjunctive sense, unless otherwise indicated. Like numbers refer to like elements throughout.

Still further, to facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not delimit the invention, except as outlined in the claims.

The term “three-dimensional structures” and the like as used herein refer generally to intended or actually fabricated three-dimensional configurations (e.g., of structural material or materials) that are intended to be used for a particular purpose. Such structures, etc. may, for example, be designed with the aid of a three-dimensional CAD system.

The term “electron beam” as used herein in various embodiments refers to any charged particle beam. The sources of charged particle beam can include an electron gun, a linear accelerator and so on.

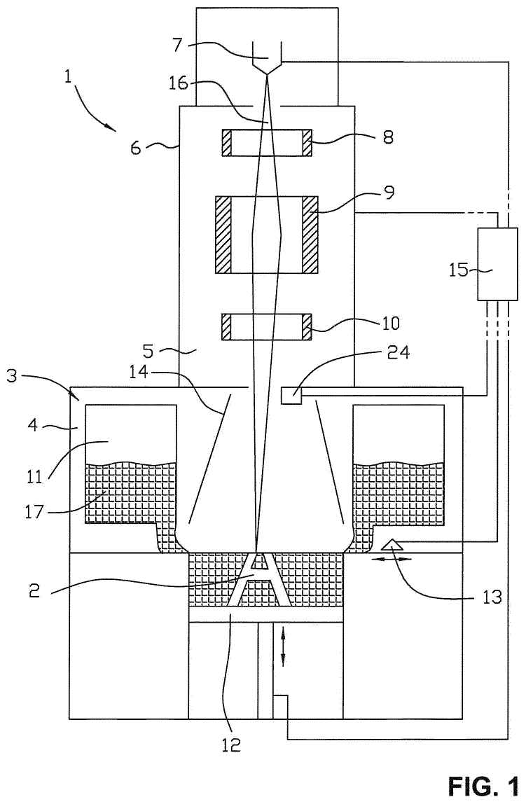

Reference is initially made to FIG. 1 disclosing a schematic illustration of a freeform fabrication or additive manufacturing apparatus 1, i.e. an electron beam melting (EBM) machine, in which the present invention is implemented. Such apparatus 1 is intended for forming a three-dimensional article 2 through successively depositing individual layers of powder material that are fused together so as to form the article 2 according to a computer model thereof.

The apparatus 1 comprises a chamber 3 having a first section 4 and a second section 5 openly connected to each other, wherein the second section 5 is delimited by an electron beam housing 6. The electron beam housing 6 and its contents is jointly known as electron beam unit (EBU). The three-dimensional article 2 is formed in the first section 4.

In accordance with prior art apparatus, the second section 5 of the disclosed embodiment of the inventive apparatus 1 comprises, i.e. the contents of the electron beam housing 6 is constituted by, an electron beam source 7, an astigmatism coil/lens 8, an electromagnetic focus coil/lens 9 and a deflection coil/lens 10, distributed successively along an axial direction of the apparatus 1. All coils/lenses located in the second section 5 are jointly named beam steering and shaping optics. It shall be pointed out that the electron beam housing 6 may comprise supplementary coils and equipment not disclosed herein.

In accordance with prior art apparatus, the first section 4 of the disclosed embodiment of the inventive apparatus 1 comprises at least one powder hopper 11, a work table 12, a powder rake or distributor 13 and a heat shield 14.

In accordance with prior art apparatus, the disclosed embodiment of the inventive apparatus 1 comprises a control unit 15. The control unit 15 comprises a computer program product, in which information is stored concerning consecutive cross sections of the three-dimensional article 2, and instructions to control the apparatus 1 to form the three-dimensional article 2 through consecutive fusion of consecutively formed cross sections. The control unit 15 is operatively connected to at least the electron beam source 7, the beam steering and shaping optics, the powder rake 13 and the work table 12.

Now the general operation of a prior art apparatus and the inventive apparatus 1 will be explained.

The electron beam source 7 is configured to generate an electron beam 16 which is used for pre heating, melting or fusing together powder material 17 provided on the work table 12 or post heat treatment of the already fused article 2. The control unit 15 is configured for controlling and managing the electron beam 16 emitted from the electron beam source 7 by means of the beam steering and shaping optics. By changing the magnetic field of the deflection coil 10 the electron beam 16 may be moved to any desired position within a predetermined maximum work area above the work table 12. The electromagnetic focus coil 9 is used for changing the size of the electron beam spot. The astigmatism coil 8 is used for changing the shape of the electron beam spot. In an example embodiment of the invention the electron beam source 7 may generate a focusable electron beam 16 with variable accelerating voltage of about 5-120 kV and with a beam power in the range of 0-15 kW during production of the three-dimensional article. The powder hoppers 11 comprise the powder material 17 to be provided on the work table or build platform 12. The powder material 17 may for instance be pure metals or metal alloys such as titanium, titanium alloys, aluminum, aluminum alloys, stainless steel, Co, Cr and/or W alloys, nickel based super alloys, etc.

The powder rake 13 is arranged to distribute a thin layer of the powder material 17 on the work table 12. During a manufacturing cycle the work table 12 will be lowered successively in relation to a fixed point in the first section 4 of the chamber 3. In order to make this movement possible, the work table 12 is arranged movably in the vertical direction, i.e. in the axial direction of the apparatus 1. This means that the work table 12 starts in an initial position, wherein a first powder material layer of appropriate and predetermined thickness is distributed. Means for lowering the work table 12 may for instance be through a servo engine equipped with a gear, adjusting screws, etc.

The electron beam 16 is directed/moved over the work table 12 causing the first powder layer to fuse in selected locations to form a first cross section of the three-dimensional article 2. The electron beam 16 is directed over the work table 12 by means of the beam steering and shaping optics from instructions given by the control unit 15. The first layer of the three-dimensional article 2 may be built directly on the work table 12, on top of a powder bed provided on the work table 12 or on a start plate, wherein the start plate may be arranged directly on the work table 12 or on top of a powder bed provided on the work table 12.

After a first layer is finished, i.e. the fusion of powder material 17 for making a first layer of the three-dimensional article 2, a second powder layer is provided on the work table 12. The thickness of the successive powder layers is determined by the distance the work table 12 is lowered in relation to the position where the preceding layer was built. After having distributed the second powder layer on the work table 12, the electron beam 16 is directed over the work table causing the second powder layer to fuse in selected locations to form a second cross section of the three-dimensional article 2. Fused portions in the second layer may be bonded to fused portions of the first layer. The fused portions in the first and second layer may be melted together by melting not only the powder in the uppermost layer but also re-melting at least a fraction of a thickness of a layer directly below the uppermost layer.

The powder 17 may be allowed to be slightly sintered during a pre-heating process. The pre-heating process is taking place before the actual fusing of the powder material in order to create a predetermined cross section of the three-dimensional article 2. The preheating may be performed in order to increase the conductivity of the powder material and/or to increase the working temperature of the powder material to be within a predetermined temperature range.

The essential features, preferred features and optional features of the present invention will now be disclosed. The present invention is primarily directed towards the calibration of the electron beam unit of an additive manufacturing apparatus 1. During calibration X-rays are generated/produced/emanated/emitted when accelerated electrons in the electron beam 16 collide with an object, and the invention makes use of the fact that X-rays generated/produced/emanated/emitted from different materials have different emission lines characteristics and different intensity.

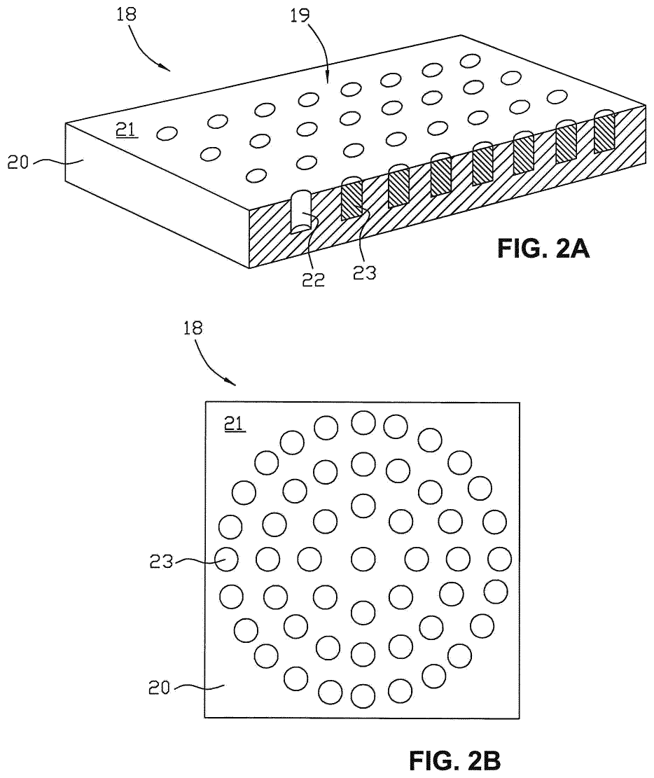

Reference is initially made to FIGS. 2A and 2B disclosing a first and a second schematic embodiment of an X-ray reference object, generally designated 18.

The X-ray reference object 18 comprises a reference surface, generally designated 19, i.e. an upper surface. During calibration the electron beam 16 from the electron beam unit is swept over the reference surface 19 having a predetermined location and orientation in the work area of the additive manufacturing apparatus 1. In the disclosed embodiments, the X-ray reference object 18 comprises a support body 20 that has a top surface 21 and comprises a plurality of recesses/holes 22 arranged in the top surface 21, i.e. the openings of the holes 22 are arranged/mouth in the top surface 21, or comprises a plurality of calibration positions arranged at the top surface 21. The holes 22 may be through holes but it is preferred that the holes 22 only extend part of the thickness of the support body 20. Preferably the holes 22 extend equal to or more than ⅕ of the thickness of the support body 20 and equal to or less than ⅘ of the thickness of the support body 20. If the hole 22 is not a through hole, the support body 20 may comprise ventilation ducts connecting the bottom of the holes 22 with the surroundings in order to avoid the possible presence of entrapped gas when the hole is plugged. The support body 20 is preferably solid, but it is also conceivable that the support body 20 underneath the top surface 21 and between the holes 22 has a material reduced structure, such as a honeycomb-structure or the like, due to weight concerns.

The support body is made of a metal or alloy comprising one or more of Copper (Cu), Aluminum (Al), Titanium (Ti) and Iron (Fe). It is most preferred that the support body is made of Copper (Cu) since it has both good heat conductivity and high melting temperature. Thus, the support body 20 is configured to manage increased energy content of the electron beam 16 without suffering from thermal damage/distortion. Thus, the support body 20 is intended to act as a heat sink.

The thickness of the support body 20 taken perpendicular to the top surface 21 is equal to or more than 5 mm and equal to or less than 50 mm. A thicker support body 20 provides better heat conductivity properties and a more robust X-ray reference object 18, but at the same time a thicker support body 20 adds weight to the X-ray reference object 18.

The X-ray reference object 18 is comprised in the additive manufacturing apparatus 1 during calibration, and is located in the work area of the additive manufacturing apparatus 1 during calibration. In certain embodiments, the X-ray reference object 18 may be constituted by a separate/unattached element that is placed at a predetermined position within the work area of the additive manufacturing apparatus 1 before calibration and then removed from the additive manufacturing apparatus 1 after calibration. In other embodiments, the X-ray reference object 18 may be attached to or otherwise integrated with the rake 13. Preferably the X-ray reference object 18 is arranged, directly or indirectly, on the work table 12 wherein the work table 12 is lowered such that the reference surface 19 is located at or near the normal production level.

According to an alternative embodiment the X-ray reference object 18 is attached to or otherwise integrated with the rake 13 (or another integrated element), which is arranged mechanically movable within the work area of the additive manufacturing apparatus 1 by the control of the additive manufacturing apparatus 1, wherein the rake 13 is moved to one or more predetermined positions during calibration. Thereby, calibration may be performed in close connection with the production, or during an interruption of the production, without the need to open and empty the additive manufacturing apparatus 1. The additive manufacturing apparatus 1 may comprise, or make use of, several X-ray reference objects 18, such as a combination of a separate/unattached element and/or an integrated element. In at least one embodiment, the separate element may comprise more holes 22 than the integrated element and may be used for monthly/weekly audits/calibrations or when a critical component has been exchanged in the additive manufacturing apparatus 1, and the integrated element may be used for more frequently performed control/calibration. Calibration may for instance be made before each new production of a three-dimensional article or after a predetermined number of productions.

According to the embodiment of FIG. 2A, the plurality of recesses/holes 22 or calibration positions of the X-ray reference object 18 are arranged to form a plurality of parallel lines. The distance between the holes 22 in a separate line may vary and/or the distance between the holes 22 in different lines may vary. In the disclosed embodiment the plurality of holes 22 are arranged in parallel rows and parallel columns making up a squared matrix. According to the embodiment of FIG. 2B, the plurality of holes 22 are arranged to form a plurality of concentric rings having different radius in relation to a center point of the X-ray reference object 18. The outer rings of holes 22 may be fragmentary if the support body 20 is squared. It shall be pointed out that also other configurations of the plurality of holes 22 are conceivable. It shall be pointed out that it is important that the exact location of all individual holes 22 is known. The outer shape of the support body 20 is of less importance, as long as the X-ray reference object 18 is configured to take a predetermined location within the apparatus 1. In those embodiments where the X-ray reference object is desirably an integrated part of the rake 13, it should be understood that the shape and/or size of the two components (as integrated) should be complementary.

As illustrated in FIG. 2A it should be understood that the holes 22 of the support body 20 and the target members 23 received therein are positioned and located on one primary (e.g., top) surface of the X-ray reference object 18. In certain embodiments, although not illustrated, more than one surface may contain the holes. It should be understood, though, that generally a surface opposing that containing the holes 22 will not have holes defined therein. Not only are opposing holes generally not necessary due to positioning of an X-ray detector 24 (described further below) relative to the X-ray reference object, but also so as to enable the opposing side to be attached to or otherwise integrated with additional components, such as the rake 13. Indeed, in those embodiments where the X-ray reference object 18 and the rake 13 are fully integrated, the surface opposing that containing the holes 22 may be that containing raking features, as such are commonly known and understood to involve.

In certain embodiments where the X-ray reference object 18 and the rake 13 are attached or at least in part integrated relative to one another, the object 18 may be adjustably connected to the rake 13. In this manner, precise alignment of both the object and the rake may be achieved, without impacting the alignment (or other precision-based requirement) of the other component. For example, with the flexibility of an adjustable connection, alignment of the object 18 may be ensured with the X-ray detector 24 (discussed further below) while simultaneously preserving (and/or otherwise ensuring) alignment of the rake with adjacently positioned components.

Returning to FIG. 2A, in order to fit an appropriate number of holes 22 in the top surface 21 of the support body 20, the opening of the holes 22 cannot be too big. It is preferred that the opening of the individual hole 22 is inscribed in a circle having a diameter equal to or more than 2 mm and equal to or less than 5 mm, preferably equal to or more than 3 mm and equal to or less than 4 mm. It is preferred that the Center to Center distance, C-C-distance, between two adjacent holes 22 is equal to or more than 20 mm and equal to or less than 50 mm, preferably equal to or more than 30 mm and equal to or less than 40 mm. The C-C-distance may be different between different pair of holes 22. The holes 22 may be drilled using precision drilling and/or precision milling as a finishing treatment or may be manufactured through etching.

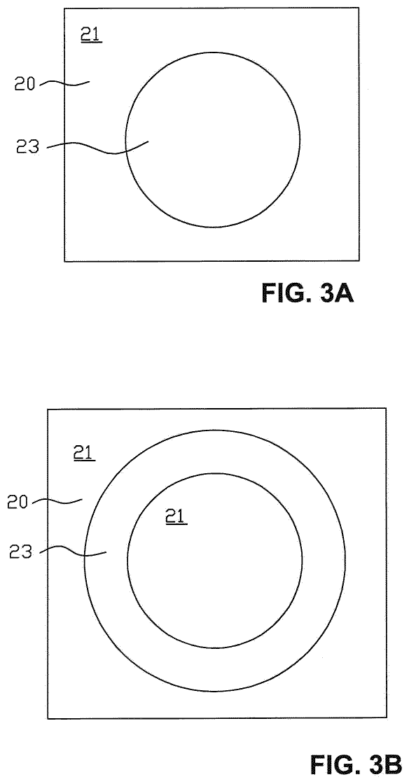

According to an exemplary embodiment the opening of the individual hole 22 of the support body 20 is circular, as shown in FIG. 3A, and according to another preferred embodiment the opening of the individual hole 22 of the support body 20 is ring-shaped, as shown in FIG. 3B. The radial distance between the inner and outer edge of the ring-shaped hole 22 is in the range 1-2 mm. When sweeping the electron beam 16 over the ring-shaped hole 22, the electron beam spot will pass four interfaces.

It shall be pointed out that the opening of the holes 22 may have other distinct shapes, such as a triangle, a quadrat, a hexagon, an octagon, a star, semi-circular, oval, etc. If the holes are not circular, the different holes 22 may have different orientation in relation to the support body 20. The X-ray reference object 18 may comprise holes 22 having different shapes and/or orientation. Where integrated with the rake, the X-ray reference object may have different surfaces with different hole configurations, at least in part opposite at least one surface having raking-facilitating features.

According to the present invention the X-ray reference object 18 comprises a plurality of target members 23 at the top surface 21 of the support body 20, providing a plurality of calibration positions. According to an exemplary embodiment, the target members 23 are inserted into the plurality of holes 22 of the support body 20. The target members 23 are made of another material than the support body 20. The material of the target members 23 shall have a higher atomic number than the material of the support body 20. Preferably one target member 23 per hole 22 and/or per calibration position, but it is conceivable to have a plurality of target members 23 inserted into each hole 22 and/or located at each calibration position. The target members 23 are made of a metal or alloy comprising one or more of Molybdenum (Mo), Tantalum (Ta), Wolfram (W), Niobium (Nb) and Zirconium (Zr). Preferably the target members 23 are made of an alloy comprising Molybdenum (Mo) and/or Niobium (Nb) together with Tantalum (Ta) and/or Wolfram (W), since such alloys has high atomic numbers and high melting temperature, i.e. high probability to generate X-rays and high resistance to thermal damage/distortion.

It shall be pointed out that all details/features described herein about the position and shape of the recesses/holes 22, is mutatis mutandis also applicable to the position and shape of the target members 23 in the embodiment having the target members 23 attached/positioned onto a top surface 21 of the support body 20 having no recesses/holes. Thus, a calibration position is equivalent to a recess/hole.

Preferably the individual hole 22 of the support body 20 and the inserted target member 23 have corresponding cross sections, and it is even more preferred that the individual hole 22 of the support body 20 and the inserted target member 23 are in tight fit with each other, i.e. no chemical substance is used to retain the target members 23 in the holes 22. Thus the target members 23 are pressed into the recesses/holes 22. For instance, the support body 20 is warmed and/or the target members 23 may be cooled before insertion, in order to facilitate insertion.

The sharper the edges/crossing between the target member 23 and the support body 20, the more improved accuracy when determining the position, size and/or shape of the electron beam spot.

According to a first embodiment the target members 23 are inserted into the plurality of recesses/holes and are in flush with the top surface 21 of the support body 20 providing a plane reference surface 19 of the X-ray reference object 18. After insertion of the target members 23 in the holes 22, the entire reference surface 19 may be machined/grinded/polished. By means of such arrangement, the edge erosion at the interface between the top surface 21 and the target members 23 will be minimized or avoided. One advantage of having a plane reference surface 19 of the X-ray reference object 18, is that if the reference surface 19 is damaged/scratched the entire reference surface 19 can be milled/polished and the X-ray reference object 18 can be used again, instead of being forced to scrap the X-ray reference object.

According to alternative embodiments the target members 23 are arranged at the top surface 21 of the support body 20 and protrude above the top surface 21 of the support body 20, or the target members 23 are arranged at the top surface 21 of the support body 20 and are located at a lower level than the top surface 21 of the support body 20. In the embodiment the target members 23 are located at a lower level than the top surface 21 of the support body 20, the walls of the hole 22 are preferably inclined towards the upper surface of the target member 23 in order to have unblocked line of sight between the electron beam unit and the target member 23.

The target members 23 may be produced by adding a layer of the target member material onto the top surface 21 of the support body 20 and then removing target member material until only the target members 23 at the calibration positions are remained at the top surface 21 of the support body 20.

In the embodiment comprising individual target members 23 added/attached to the top surface 21 of the support body 20, the target members 23 may for instance be attached by brazing.

The additive manufacturing apparatus 1 also comprises an X-ray detector 24 in order to detect at least the X-rays generated/emanated when the electron beam 16 is swept over the target members 23 of the X-ray reference object 18, when the electron beam 16 is swept over the reference surface 21 of the X-ray reference object 18. The X-ray detector 24 is operatively connected to the control unit 15, wherein the control unit is configured for processing the detected signals/X-rays in order to determine the shape, size and/or position of the electron beam spot. The X-ray detector 24 is located close to the opening between the first section 4 and the second section 5 of the chamber 3. The additive manufacturing apparatus 1 may comprise several X-ray detectors located at different positions in the chamber 3 and/or oriented in different directions.

The electron beam 16 is a continuous stream of electrons and the electron beam spot has a diameter in the range 50-400 μm that is more or less proportional to the electron beam current, i.e. the higher the electron beam current the bigger/larger electron beam spot. The electron beam current of the electron beam 16 is equal to or more than 1 mA and equal to or less than 50 mA, preferably equal to or more than 5 mA and equal to or less than 30 mA. The accelerating voltage of the electron beam 16 during calibration is equal to or more than 30 kV and equal to or less than 120 kV. Thereto, the sweeping speed of the electron beam 16 is equal to or less than 25 m/s, preferably equal to or less than 20 m/s, and the electron beam spot is incrementally moved up to 400 000 times per second. Thus, if the sweeping speed is 20 m/s and the electron beam spot is moved 400 000 times per second, the electron beam spot is moved 50 μm each time, i.e. the resolution/precision is 50 μm. A slower sweeping speed will provide a better accuracy, i.e. if the sweeping speed is 10 m/s the resolution will be 25 μm, and if the sweeping speed is 2 m/s the resolution will be 5 μm. The resolution shall be equal to or less than 20% of the electron beam spot diameter, preferably equal to or less than 10%. Thus, when using a smaller electron beam spot diameter the sweeping speed must be decreased correspondingly.

When the electron beam spot only hits the top surface 21 of the support body 20, all generated/emanated X-rays have characteristics corresponding to the material in the support body 20, but when the leading edge of the electron beam spot hits the edge region of the target member 23 some of the X-rays generated/emanated have characteristics corresponding to the material in the target member 23. As long as a part of the electron beam spot hits the target member 23, some of the generated/emanated X-rays have characteristics corresponding to the material in the target member 23, but when the trailing edge of the electron beam spot leaves the edge region of the target member 23 all generated/emanated X-rays have characteristics corresponding to the material in the support body 20.

Thus, when the electron beam 16 is swept over a single target member 23 in one or more predetermined direction, the X-ray detector 24 detects the X-rays originating from the X-ray reference object 18, and based on the detected X-rays originating from the target member 23 the control unit 15 determines at least one real value of a parameter of the electron beam spot at the reference surface 21 of the X-ray reference object 18, i.e. shape, size and/or position of the electron beam spot. The at least one real value of a parameter of the electron beam spot is compared to a corresponding target value of the parameter of the electron beam spot in the control unit 15, wherein the control of the electron beam unit is adjusted/calibrated in the control unit 15 when a deviation is determined, in order to have the at least one real value of a parameter of the electron beam spot approaching the target value.

Thus, when it is determined that the electron beam spot is misshaped, the astigmatism coil 8 is corrected to obtain correct electron beam shape. The adjustment/calibration is preferable repeated until correct shape is achieved. By sweeping the electron beam 16 in a plurality of directions over the target member 23, the shape of the electron beam spot can be determined with high accuracy.

When it is determined that the electron beam spot has incorrect size, the electromagnetic focus coil 9 is adjusted to obtain correct electron beam size. The adjustment/calibration is preferable repeated until correct size is achieved. By sweeping the electron beam 16 in a plurality of directions over the target member 23, the size of the electron beam spot can be determined with high accuracy.

When it is determined that the electron beam spot has incorrect position, the deflection coil 10 is adjusted to obtain correct electron beam spot position. The adjustment/calibration is preferable repeated until correct position is achieved. By sweeping the electron beam 16 in a plurality of directions over the target member 23, the position of the electron beam spot can be determined with high accuracy.

Due to the present invention, i.e. solid target members 23 inserted into holes of the support body 20, the electron beam 16 may be swept over the same target member 23 a great number of times during extended time without running the risk of damaging the target member 23 or the support body 20, thanks to the excellent heat distribution and dissipation of the inventive X-ray reference object 18.

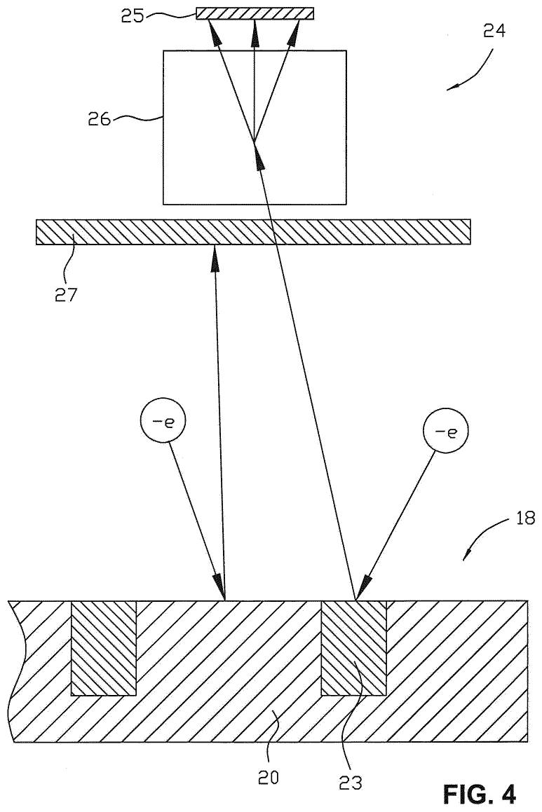

Reference is now made to FIG. 4, disclosing an inventive X-ray detector 24, wherein the additive manufacturing apparatus 1 preferably comprises such an X-ray detector. Preferably, the X-ray detector 24 is configured to detect/absorb emission lines having photon energies equal to or more than 15 keV and equal to or less than 120 keV.

The inventive X-ray detector 24 comprises a photo detector 25, a scintillator 26 arranged in front of the photo detector 25 and a spectral filter 27 arranged in front of the scintillator 26, so that X-rays originating from the X-ray reference object 18 will penetrates through the spectral filter 27 and then be absorbed by the scintillator 26.

The spectral filter 27 is configured to suppress X-ray bremsstrahlung, K-level emission lines and/or L-level emission lines having photon energies equal to or less than 15 keV, in order to decrease the background/noise signals from the support body 20, i.e. increase the accuracy of the detection of X-rays originating from the target members 23 by improving the signal/noise ratio. The spectral filter 27 is preferably a sheet of metal, for instance made of a metal or alloy comprising one or more of Iron (Fe), Cobalt (Co), Nickel (Ni) and Aluminum (Al). The thickness of the spectral filter 27 is equal to or more than 0.1 mm and equal to or less than 5 mm. The material of the spectral filter 27 may have an absorption edge suppressing the emission lines of the material of the support body 20 but leaving the emission lines of the material of the target member 23 unaffected.

The scintillator 26 is preferably constituted by a Lutetium (Lu) based crystal, preferably doped with Cerium (Ce), wherein the scintillator 26 is a glass-like crystal. Such a crystal has high density and high absorption characteristics. According to one embodiment such scintillator 26 emits light having a wavelength of about 420 nm. The scintillator 26 is preferably not hygroscopic. The absorption coefficient of the scintillator 26 is equal to or more than 90%, preferably equal to or more than 98%. The decay time of the scintillator 26 is equal to or less than 100 ns, preferably equal to or less than 50 ns, and most preferably equal to or less than 35 ns.

The light yield, i.e. the amplification, of the scintillator 26 is equal to or more than 10 photons/keV, preferably equal to or more than 30 photons/keV. For example, if the light yield of the scintillator 26 is about 35 photons/keV and one of the emission lines of the X-ray emanated from the target member 23 has photon energy of about 60 keV, the scintillator 26 will emit more than 2000 photons in the visible light spectra per X-ray photon. The photons in the visible light spectra are detected by the photo detector 25, preferably optimized for wavelengths in the range 400-450 nm. The photo detector 25 may be constituted by a PIN-photo diode or a photo multiplier. The active area of the photo detector 25 is inscribed in a circle having a diameter equal to or less than 15 mm, preferably equal to or less than 10 mm, most preferably equal to or less than 5 mm. The active area of the scintillator 26 is inscribed in a circle having a diameter equal to or less than 15 mm, preferably equal to or less than 10 mm, and most preferably equal to or less than 5 mm. Preferably the active area of the scintillator 26 is equal to or less than the active area of the photo detector 25.

In another aspect of the invention it is provided a computer program product comprising at least one non-transitory computer-readable storage medium having computer-readable program code portions, or program elements, embedded therein, wherein the computer-readable program code portions are configured to cause the additive manufacturing apparatus 1 to execute the steps of the described calibration method in order to calibrate the electron beam unit of the additive manufacturing apparatus 1. The computer program product is also configured, when executed on a computer, to implement a method for forming at least one three dimensional article through successive joining of parts of a material layer.

The program element may be installed in one or more non-transitory computer readable storage mediums. The non-transitory computer readable storage mediums and/or the program element may be associated with a control unit, as described elsewhere herein. The computer readable storage mediums and the program elements, which may comprise non-transitory computer readable program code portions embodied therein, may further be contained within one or more non-transitory computer program products. According to various embodiments, the method described elsewhere herein may be computer-implemented, for example in conjunction with one or more processors and/or memory storage areas.

As mentioned, various embodiments of the present invention may be implemented in various ways, including as non-transitory computer program products. A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid state drive (SSD), solid state card (SSC), solid state module (SSM)), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc compact disc-rewritable (CD-RW), digital versatile disc (DVD), Blu-ray disc (BD), any other non-transitory optical medium, and/or the like. Such a nonvolatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory VRAM, cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present invention may also be implemented as methods, apparatus, systems, computing devices, computing entities, and/or the like, as have been described elsewhere herein. As such, embodiments of the present invention may take the form of an apparatus, system, computing device, computing entity, and/or the like executing instructions stored on a computer-readable storage medium to perform certain steps or operations. However, embodiments of the present invention may also take the form of an entirely hardware embodiment performing certain steps or operations.

Various embodiments are described below with reference to block diagrams and flowchart illustrations of apparatuses, methods, systems, and computer program products. It should be understood that each block of any of the block diagrams and flowchart illustrations, respectively, may be implemented in part by computer program instructions, e.g., as logical steps or operations executing on a processor in a computing system. These computer program instructions may be loaded onto a computer, such as a special purpose computer or other programmable data processing apparatus to produce a specifically-configured machine, such that the instructions which execute on the computer or other programmable data processing apparatus implement the functions specified in the flowchart block or blocks.

These computer program instructions may also be stored in a computer-readable memory that can direct a computer or other programmable data processing apparatus to function in a particular manner, such that the instructions stored in the computer-readable memory produce an article of manufacture including computer-readable instructions for implementing the functionality specified in the flowchart block or blocks. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide operations for implementing the functions specified in the flowchart block or blocks.

Accordingly, blocks of the block diagrams and flowchart illustrations support various combinations for performing the specified functions, combinations of operations for performing the specified functions and program instructions for performing the specified functions. It should also be understood that each block of the block diagrams and flowchart illustrations, and combinations of blocks in the block diagrams and flowchart illustrations, could be implemented by special purpose hardware-based computer systems that perform the specified functions or operations, or combinations of special purpose hardware and computer instructions.

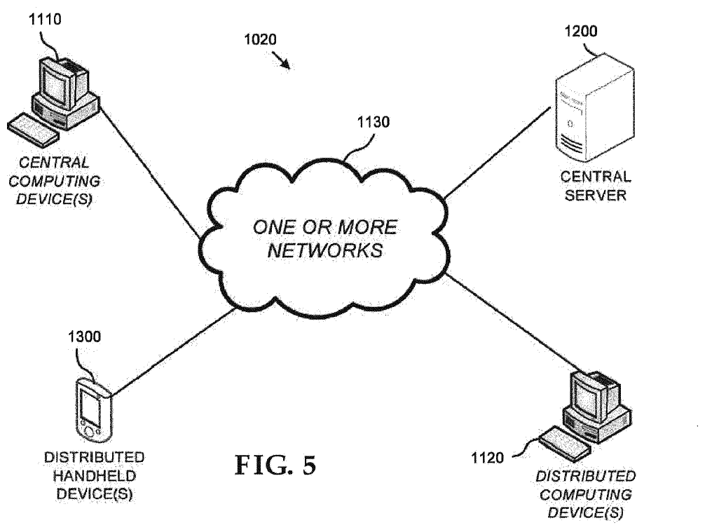

FIG. 5 is a block diagram of an exemplary system 1020 that can be used in conjunction with various embodiments of the present invention. In at least the illustrated embodiment, the system 1020 may include one or more central computing devices 1110, one or more distributed computing devices 1120, and one or more distributed handheld or mobile devices 1300, all configured in communication with a central server 1200 (or control unit) via one or more networks 1130. While FIG. 5 illustrates the various system entities as separate, standalone entities, the various embodiments are not limited to this particular architecture.

According to various embodiments of the present invention, the one or more networks 1130 may be capable of supporting communication in accordance with anyone or more of a number of second-generation (2G), 2.5G, third-generation (3G), and/or fourth generation (4G) mobile communication protocols, or the like. More particularly, the one or more networks 1130 may be capable of supporting communication in accordance with 2G wireless communication protocols IS-136 (TDMA), GSM, and IS-95 (CDMA). Also, for example, the one or more networks 1130 may be capable of supporting communication in accordance with 2.5G wireless communication protocols GPRS, Enhanced Data GSM Environment (EDGE), or the like. In addition, for example, the one or more networks 1130 may be capable of supporting communication in accordance with 3G wireless communication protocols such as Universal Mobile Telephone System (UMTS) network employing Wideband Code Division Multiple Access (WCDMA) radio access technology. Some narrow-band AMPS (NAMPS), as well as TACS, network(s) may also benefit from embodiments of the present invention, as should dual or higher mode mobile stations (e.g., digital/analog or TDMA/CDMA/analog phones). As yet another example, each of the components of the system 1020 may be configured to communicate with one another in accordance with techniques such as, for example, radio frequency (RF), Bluetooth™, infrared (IrDA), or any of a number of different wired or wireless networking techniques, including a wired or wireless Personal Area Network (“PAN”), Local Area Network (“LAN”), Metropolitan Area Network (“MAN”), Wide Area Network (“WAN”), or the like.

Although the device(s) 1110-1300 are illustrated in FIG. 5 as communicating with one another over the same network 1130, these devices may likewise communicate over multiple, separate networks.

According to one embodiment, in addition to receiving data from the server 1200, the distributed devices 1110, 1120, and/or 1300 may be further configured to collect and transmit data on their own. In various embodiments, the devices 1110, 1120, and/or 1300 may be capable of receiving data via one or more input units or devices, such as a keypad, touchpad, barcode scanner, radio frequency identification (RFID) reader, interface card (e.g., modem, etc.) or receiver. The devices 1110, 1120, and/or 1300 may further be capable of storing data to one or more volatile or non-volatile memory modules, and outputting the data via one or more output units or devices, for example, by displaying data to the user operating the device, or by transmitting data, for example over the one or more networks 1130.

In various embodiments, the server 1200 includes various systems for performing one or more functions in accordance with various embodiments of the present invention, including those more particularly shown and described herein. It should be understood, however, that the server 1200 might include a variety of alternative devices for performing one or more like functions, without departing from the spirit and scope of the present invention. For example, at least a portion of the server 1200, in certain embodiments, may be located on the distributed device(s) 1110, 1120, and/or the handheld or mobile device(s) 1300, as may be desirable for particular applications. As will be described in further detail below, in at least one embodiment, the handheld or mobile device(s) 1300 may contain one or more mobile applications 1330 which may be configured so as to provide a user interface for communication with the server 1200, all as will be likewise described in further detail below.

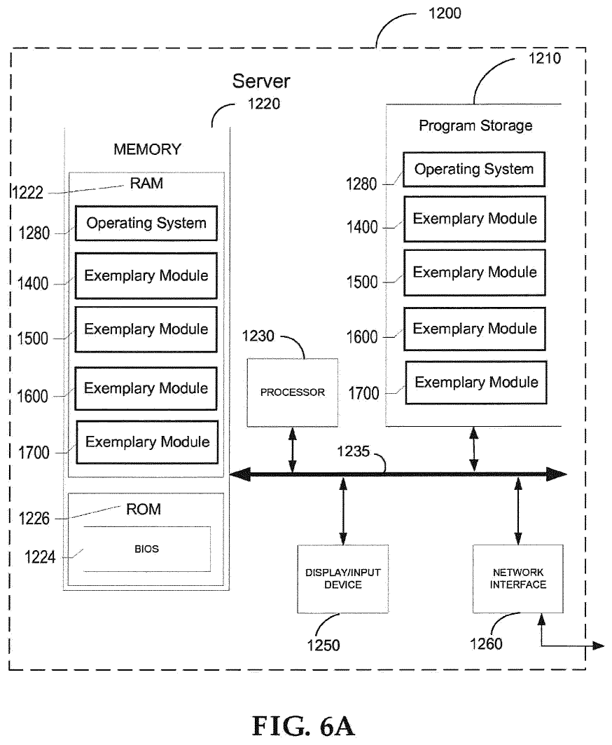

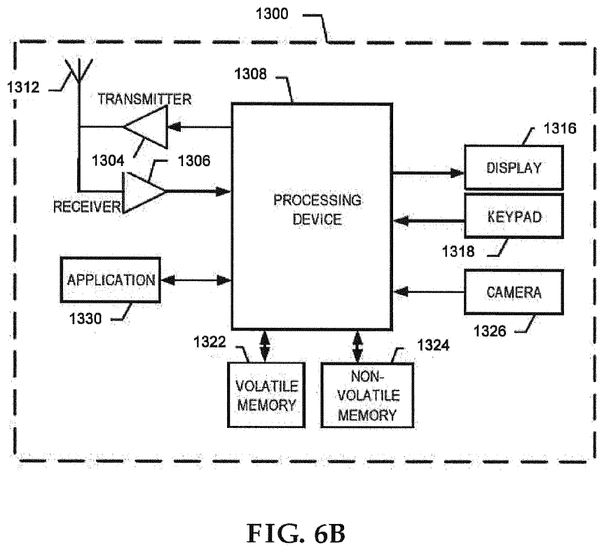

FIG. 6A is a schematic diagram of the server 1200 according to various embodiments. The server 1200 includes a processor 1230 that communicates with other elements within the server via a system interface or bus 1235. Also included in the server 1200 is a display/input device 1250 for receiving and displaying data. This display/input device 1250 may be, for example, a keyboard or pointing device that is used in combination with a monitor. The server 1200 further includes memory 1220, which typically includes both read only memory (ROM) 1226 and random access memory (RAM) 1222. The server's ROM 1226 is used to store a basic input/output system 1224 (BIOS), containing the basic routines that help to transfer information between elements within the server 1200. Various ROM and RAM configurations have been previously described herein.

In addition, the server 1200 includes at least one storage device or program storage 210, such as a hard disk drive, a floppy disk drive, a CD Rom drive, or optical disk drive, for storing information on various computer-readable media, such as a hard disk, a removable magnetic disk, or a CD-ROM disk. As will be appreciated by one of ordinary skill in the art, each of these storage devices 1210 are connected to the system bus 1235 by an appropriate interface. The storage devices 1210 and their associated computer-readable media provide nonvolatile storage for a personal computer. As will be appreciated by one of ordinary skill in the art, the computer-readable media described above could be replaced by any other type of computer-readable media known in the art. Such media include, for example, magnetic cassettes, flash memory cards, digital video disks, and Bernoulli cartridges.

Although not shown, according to an embodiment, the storage device 1210 and/or memory of the server 1200 may further provide the functions of a data storage device, which may store historical and/or current delivery data and delivery conditions that may be accessed by the server 1200. In this regard, the storage device 1210 may comprise one or more databases. The term “database” refers to a structured collection of records or data that is stored in a computer system, such as via a relational database, hierarchical database, or network database and as such, should not be construed in a limiting fashion.

A number of program modules (e.g., exemplary modules 1400-1700) comprising, for example, one or more computer-readable program code portions executable by the processor 1230, may be stored by the various storage devices 1210 and within RAM 1222. Such program modules may also include an operating system 1280. In these and other embodiments, the various modules 1400, 1500, 1600, 1700 control certain aspects of the operation of the server 1200 with the assistance of the processor 1230 and operating system 1280. In still other embodiments, it should be understood that one or more additional and/or alternative modules may also be provided, without departing from the scope and nature of the present invention.

In various embodiments, the program modules 1400, 1500, 1600, 1700 are executed by the server 1200 and are configured to generate one or more graphical user interfaces, reports, instructions, and/or notifications/alerts, all accessible and/or transmittable to various users of the system 1020. In certain embodiments, the user interfaces, reports, instructions, and/or notifications/alerts may be accessible via one or more networks 1130, which may include the Internet or other feasible communications network, as previously discussed.

In various embodiments, it should also be understood that one or more of the modules 1400, 1500, 1600, 1700 may be alternatively and/or additionally (e.g., in duplicate) stored locally on one or more of the devices 1110, 1120, and/or 1300 and may be executed by one or more processors of the same. According to various embodiments, the modules 1400, 1500, 1600, 1700 may send data to, receive data from, and utilize data contained in one or more databases, which may be comprised of one or more separate, linked and/or networked databases.

Also located within the server 1200 is a network interface 1260 for interfacing and communicating with other elements of the one or more networks 1130. It will be appreciated by one of ordinary skill in the art that one or more of the server 1200 components may be located geographically remotely from other server components. Furthermore, one or more of the server 1200 components may be combined, and/or additional components performing functions described herein may also be included in the server.

While the foregoing describes a single processor 1230, as one of ordinary skill in the art will recognize, the server 1200 may comprise multiple processors operating in conjunction with one another to perform the functionality described herein. In addition to the memory 1220, the processor 1230 can also be connected to at least one interface or other means for displaying, transmitting and/or receiving data, content or the like. In this regard, the interface(s) can include at least one communication interface or other means for transmitting and/or receiving data, content or the like, as well as at least one user interface that can include a display and/or a user input interface” as will be described in further detail below. The user input interface, in turn, can comprise any of a number of devices allowing the entity to receive data from a user, such as a keypad, a touch display, a joystick or other input device.

Still further, while reference is made to the “server” 1200, as one of ordinary skill in the art will recognize, embodiments of the present invention are not limited to traditionally defined server architectures. Still further, the system of embodiments of the present invention is not limited to a single server, or similar network entity or mainframe computer system. Other similar architectures including one or more network entities operating in conjunction with one another to provide the functionality described herein may likewise be used without departing from the spirit and scope of embodiments of the present invention. For example, a mesh network of two or more personal computers (PCs), similar electronic devices, or handheld portable devices, collaborating with one another to provide the functionality described herein in association with the server 1200 may likewise be used without departing from the spirit and scope of embodiments of the present invention.

According to various embodiments, many individual steps of a process may or may not be carried out utilizing the computer systems and/or servers described herein, and the degree of computer implementation may vary, as may be desirable and/or beneficial for one or more particular applications.

FIG. 6B provides an illustrative schematic representative of a mobile device 1300 that can be used in conjunction with various embodiments of the present invention. Mobile devices 1300 can be operated by various parties. As shown in FIG. 6B, a mobile device 1300 may include an antenna 1312, a transmitter 1304 (e.g., radio), a receiver 1306 (e.g., radio), and a processing element 1308 that provides signals to and receives signals from the transmitter 1304 and receiver 1306, respectively.

The signals provided to and received from the transmitter 1304 and the receiver 1306, respectively, may include signaling data in accordance with an air interface standard of applicable wireless systems to communicate with various entities, such as the server 1200, the distributed devices 1110, 1120, and/or the like. In this regard, the mobile device 1300 may be capable of operating with one or more air interface standards, communication protocols, modulation types, and access types. More particularly, the mobile device 1300 may operate in accordance with any of a number of wireless communication standards and protocols. In a particular embodiment, the mobile device 1300 may operate in accordance with multiple wireless communication standards and protocols, such as GPRS, UMTS, CDMA2000, 1×RTT, WCDMA, TD-SCDMA, LTE, E-UTRAN, EVDO, HSPA, HSDPA, Wi-Fi, WiMAX, UWB, IR protocols, Bluetooth protocols, USB protocols, and/or any other wireless protocol.

Via these communication standards and protocols, the mobile device 1300 may according to various embodiments communicate with various other entities using concepts such as Unstructured Supplementary Service data (USSD), Short Message Service (SMS), Multimedia Messaging Service (MMS), Dual-Tone Multi-Frequency Signaling (DTMF), and/or Subscriber Identity Module Dialer (SIM dialer). The mobile device 1300 can also download changes, addons, and updates, for instance, to its firmware, software (e.g., including executable instructions, applications, program modules), and operating system.

According to one embodiment, the mobile device 1300 may include a location determining device and/or functionality. For example, the mobile device 1300 may include a GPS module adapted to acquire, for example, latitude, longitude, altitude, geocode, course, and/or speed data. In one embodiment, the GPS module acquires data, sometimes known as ephemeris data, by identifying the number of satellites in view and the relative positions of those satellites.

The mobile device 1300 may also comprise a user interface (that can include a display 1316 coupled to a processing element 1308) and/or a user input interface (coupled to a processing element 308). The user input interface can comprise any of a number of devices allowing the mobile device 1300 to receive data, such as a keypad 1318 (hard or soft), a touch display, voice or motion interfaces, or other input device. In embodiments including a keypad 1318, the keypad can include (or cause display of) the conventional numeric (0-9) and related keys (#, *), and other keys used for operating the mobile device 1300 and may include a full set of alphabetic keys or set of keys that may be activated to provide a full set of alphanumeric keys. In addition to providing input, the user input interface can be used, for example, to activate or deactivate certain functions, such as screen savers and/or sleep modes.

The mobile device 1300 can also include volatile storage or memory 1322 and/or non-volatile storage or memory 1324, which can be embedded and/or may be removable. For example, the non-volatile memory may be ROM, PROM, EPROM, EEPROM, flash memory, MMCs, SD memory cards, Memory Sticks, CBRAM, PRAM, FeRAM, RRAM, SONOS, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. The volatile and non-volatile storage or memory can store databases, database instances, database mapping systems, data, applications, programs, program modules, scripts, source code, object code, byte code, compiled code, interpreted code, machine code, executable instructions, and/or the like to implement the functions of the mobile device 1300.

The mobile device 1300 may also include one or more of a camera 1326 and a mobile application 1330. The camera 1326 may be configured according to various embodiments as an additional and/or alternative data collection feature, whereby one or more items may be read, stored, and/or transmitted by the mobile device 1300 via the camera. The mobile application 1330 may further provide a feature via which various tasks may be performed with the mobile device 1300. Various configurations may be provided, as may be desirable for one or more users of the mobile device 1300 and the system 1020 as a whole.

The invention is not limited only to the embodiments described above and shown in the drawings, which primarily have an illustrative and exemplifying purpose. This patent application is intended to cover all adjustments and variants of the preferred embodiments described herein, thus the present invention is defined by the wording of the appended claims and the equivalents thereof. Thus, the equipment may be modified in all kinds of ways within the scope of the appended claims.

It shall be pointed out that the present invention has been described having the support body made of a first material and the target members made by a second material. However, it shall be realized that the support body may be made of the second material and the target members may be made by the first material.

It shall also be pointed out that all information about/concerning terms such as above, under, upper, lower, etc., shall be interpreted/read having the equipment oriented according to the figures, having the drawings oriented such that the references can be properly read. Thus, such terms only indicates mutual relations in the shown embodiments, which relations may be changed if the inventive equipment is provided with another structure/design.

It shall also be pointed out that even thus it is not explicitly stated that features from a specific embodiment may be combined with features from another embodiment, the combination shall be considered obvious, if the combination is possible.

Throughout this specification and the claims which follows, unless the context requires otherwise, the word “comprise”, and variations such as “comprises” or “comprising”, will be understood to imply the inclusion of a stated integer or steps or group of integers or steps but not the exclusion of any other integer or step or group of integers or steps.

1. An X-ray reference object (18) for calibrating an electron beam unit in an additive manufacturing apparatus (1) by detecting X-rays generated by sweeping an electron beam (16) from the electron beam unit over a reference surface (19) of the X-ray reference object (18) and processing the detected signals, the X-ray reference object (18) comprising a support body (20) that has a top surface (21), wherein the X-ray reference object (18) comprises a plurality of recesses/holes (22) in at least one surface of the support body.

2. The X-ray reference object (18) according to claim 1, wherein the X-ray reference object is attached to a rake of the additive manufacturing apparatus.

3. The X-ray reference object (18) according to claim 2, wherein the rake is movable.

4. The X-ray reference object (18) according to claim 2, wherein the object is adjustably and selectively removably attached to the rake.

5. The X-ray reference object (18) according to claim 1, wherein the X-ray reference object is an integrated portion of a rake of the additive manufacturing apparatus.

6. The X-ray reference object (18) according to claim 5, wherein the at least one surface comprising the plurality of recesses/holes is opposite a surface of the rake having rake-like characteristics.

7. The X-ray reference object (18) according to claim 1, wherein a plurality of target members (23) is inserted into the plurality of recesses (22).

8. The X-ray reference object (18) according to claim 7, wherein the target members (23) are flush with the top surface (21) of the support body (20) providing a plane reference surface (19) of the X-ray reference object (18).

9. The X-ray reference object (18) according to claim 7, wherein the target members (23) protrude above the top surface (21) of the support body (20).

10. The X-ray reference object (18) according to claim 7, wherein the target members (23) are located at a lower level than the top surface (21) of the support body (20).

11. The X-ray reference object (18) according to claim 7, wherein the individual recess/hole (22) of the support body (20) and the inserted target member (23) have corresponding cross sections.

12. The X-ray reference object (18) according to claim 7, wherein the individual hole (22) of the support body (20) and the inserted target member (23) are in tight fit with each other.

13. The X-ray reference object (18) according to claim 1, wherein the opening of the individual hole (22) of the support body (20) is circular.

14. The X-ray reference object (18) according to claim 1, wherein the opening of the individual hole (22) of the support body (20) is ring-shaped.

15. The X-ray reference object (18) according to claim 1, wherein the opening of the individual hole (22) of the support body (20) is inscribed in a circle having a diameter equal to or more than 2 mm and equal to or less than 5 mm.

16. The X-ray reference object (18) according to claim 1, wherein the center-to-center distance between two adjacent holes (22) of the support body (20) is equal to or more than 20 mm and equal to or less than 50 mm.

17. The X-ray reference object (18) according to claim 1, wherein the plurality of holes (22) of the support body (20) are arranged to form a plurality of concentric rings having different radius in relation to a center point of the X-ray reference object (18).

18. The X-ray reference object (18) according to claim 1, wherein the plurality of holes (22) of the support body (20) are arranged to form a plurality of parallel lines.

19. The X-ray reference object (18) according to claim 1, wherein the support body (20) is solid and made of a metal or alloy comprising one or more of Copper (Cu), Aluminum (Al), Titanium (Ti) and Iron (Fe), preferably Copper (Cu).

20. The X-ray reference object (18) according to claim 1, wherein the target members (23) are made of a metal or alloy comprising one or more of Molybdenum (Mo), Tantalum (Ta), Wolfram (W), Niobium (Nb) and Zirconium (Zr).

21.-70. (canceled)
